(19) United States
(12) Patent Application Publication
(10) Pub. No.: US 2026/0188977 A1
(43) Pub. Date: Jul. 2, 2026

(54) SURFACE EMITTING LASER DEVICE AND MANUFACTURING METHOD THEREOF

(71) Applicant: Hon Hai Precision Industry Co., Ltd., New Taipei City (TW)

(72) Inventors: Yu-Heng HONG, New Taipei City (TW); Hao-Chung KUO, New Taipei City (TW); Hsin-Chieh Yu, New Taipei City (TW); Hui-Tzu Yeh, New Taipei City (TW)

(73) Assignee: Hon Hai Precision Industry Co., Ltd., New Taipei City (TW)

(21) Appl. No.: 19/086,162

(22) Filed: Mar. 21, 2025

(30) Foreign Application Priority Data
Dec. 30, 2024 (TW) 113151466

(51) Int. Cl. H01S 5/183

(52) U.S. Cl. CPC H01S 5/18361

(57) ABSTRACT

Provided is a surface emitting laser device including a first type distributed Bragg reflective layer, an active layer, a second type distributed Bragg reflective layer, and an oxide layer. The active layer is disposed on the first type distributed Bragg reflective layer. The second type distributed Bragg reflective layer is disposed on the active layer. The oxide layer is disposed at a side of the second type distributed Bragg reflective layer adjacent to the active layer. The oxide layer has an opening, and light emitted by the active layer passes through the opening. The second type distributed Bragg reflective layer has multiple voids therein. The voids are located above the opening and on a light path of the light emitted by the active layer. Provided is also a manufacturing method of a surface emitting laser device.

### CROSS-REFERENCE TO RELATED APPLICATION

This application claims the priority benefit of Taiwan application serial no. 113151466 filed on Dec. 30, 2024. The entirety of the above-mentioned patent application is hereby incorporated by reference herein and made a part of this specification.

### BACKGROUND

### Technical Field

The disclosure relates to a laser and a manufacturing method thereof, and particularly relates to a surface emitting laser device and a manufacturing method thereof.

### Related Art

Regarding the current manufacturing process of surface emitting lasers, such as those made from gallium arsenide series materials, most of them may, during the epitaxial growth process, form a high aluminum content oxide layer above the active layer, which provides a current confinement structure (i.e., selective oxide layer) in subsequent processes by means of high-temperature wet oxidation. In addition to providing gain guiding, it also has a refractive index guiding effect, therefore achieving superior operating characteristics compared to surface emitting lasers made by traditional ion implantation methods.

However, in order to improve the component operating characteristics, control the output beam divergence angle, and achieve high-speed modulation, the method of achieving single transverse mode output for the surface emitting laser is usually adopted. But since the position of the selective oxide layer is usually very close to the gain region of the active layer, to obtain a single transverse mode laser output, for a surface emitting laser with an emission wavelength of 850 nanometers, the required oxidation-confined current aperture usually needs to be less than 5 micrometers. For the selective oxidation process, it is quite difficult to precisely control the oxidation aperture to be below 5 micrometers, and the reproducibility is not high.

Currently, some research teams are also studying single transverse mode output. The methods they use mostly utilize processing techniques or propose new structures to suppress higher order transverse modes (i.e., multiple transverse modes) to achieve the effect of single transverse mode output. However, most of the methods currently adopted require additional process steps, including photolithography, anisotropic etching processes, etc. This may increase the number of masks and photolithography steps required for the process, thus inevitably leading to a decrease in process yield and an increase in cost.

### SUMMARY

The disclosure provides a surface emitting laser device, capable of achieving single transverse mode output in a situation with lower cost and higher yield.

The disclosure provides a manufacturing method of a surface emitting laser device, capable of utilizing simple, lower-cost, and higher-yield process steps to manufacture a surface emitting laser device that can achieve single transverse mode output.

An embodiment of the disclosure proposes a surface emitting laser device, including a first type distributed Bragg reflective layer, an active layer, a second type distributed Bragg reflective layer, and an oxide layer. The active layer is disposed on the first type distributed Bragg reflective layer, and the second type distributed Bragg reflective layer is disposed on the active layer. The oxide layer is disposed on a side of the second type distributed Bragg reflective layer adjacent to the active layer. The oxide layer has an opening, and light emitted by the active layer passes through the opening. The second type distributed Bragg reflective layer has multiple voids, the voids are located above the opening and on a light path of the light emitted by the active layer.

An embodiment of the disclosure proposes a manufacturing method of a surface emitting laser device, including the following. A surface emitting laser chip is provided, wherein the surface emitting laser chip includes a first type distributed Bragg reflective layer, an active layer, a second type distributed Bragg reflective layer, and an oxide layer. The active layer is disposed on the first type distributed Bragg reflective layer. The second type distributed Bragg reflective layer is disposed on the active layer. The oxide layer is disposed on a side of the second type distributed Bragg reflective layer adjacent to the active layer. The oxide layer has an opening for allowing light emitted by the active layer to pass through. Multiple voids are formed in the second type distributed Bragg reflective layer above the opening.

In the surface emitting laser device according to the embodiment of the disclosure, the second type distributed Bragg reflective layer has multiple voids located above the opening and on the light path of the light emitted by the active layer. The distributed Bragg reflection characteristic at the voids is destroyed, thereby suppressing laser light with multiple transverse modes from the active layer. Therefore, the surface emitting laser device according to the embodiment of the disclosure may achieve single transverse mode output by means of a simple structure, while having lower cost and higher yield. In the manufacturing method of the surface emitting laser device according to the embodiment of the disclosure, multiple voids are formed in the second type distributed Bragg reflective layer above the opening, wherein the distributed Bragg reflection characteristic at the voids is destroyed, thereby suppressing laser light with multiple transverse modes from the active layer. Therefore, the manufacturing method of the surface emitting laser device according to the embodiment of the disclosure may implement simple, lower-cost, and higher-yield process steps to manufacture a surface emitting laser device that can achieve single transverse mode output.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a cross-sectional schematic diagram illustrating a surface emitting laser device according to an embodiment of the disclosure.

FIG. 2 is a perspective schematic diagram of the surface emitting laser device of FIG. 1.

FIG. 3 illustrates the relationship between a transverse mode of laser light and voids in FIG. 1.

FIG. 4A and FIG. 4B are cross-sectional schematic diagrams used to illustrate the process flow of a manufacturing method for a surface emitting laser device according to an embodiment of the disclosure.

FIG. 5A is a distribution diagram of E² field intensity and refractive index relative to a profile depth of a surface emitting laser chip in FIG. 4A.

FIG. 5B is a reflectance spectrum diagram of the surface emitting laser chip in FIG. 4A.

FIG. 6A is a distribution diagram of E² field intensity and refractive index relative to a profile depth of the surface emitting laser device in FIG. 4B.

FIG. 6B is a reflectance spectrum diagram of a surface emitting laser chip in FIG. 4B.

FIG. 7 is a cross-sectional schematic diagram of a surface emitting laser device according to another embodiment of the disclosure.

### DESCRIPTION OF THE EMBODIMENTS

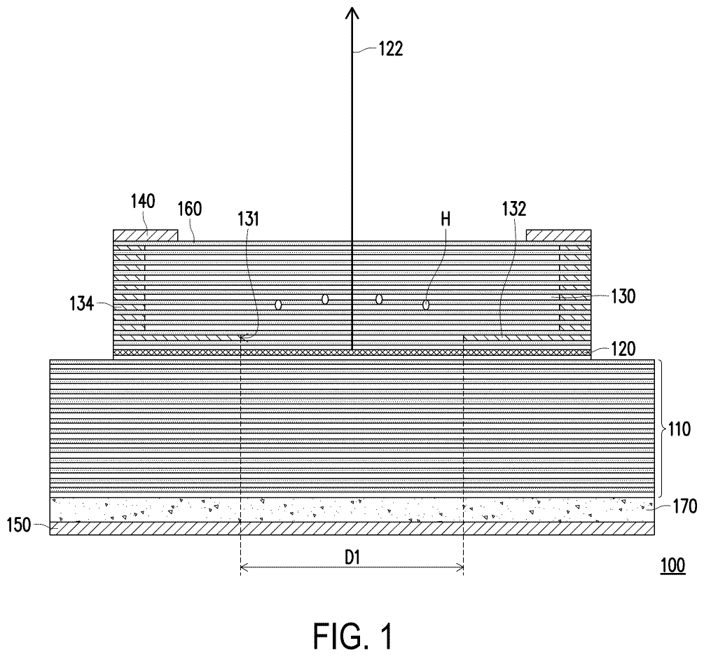

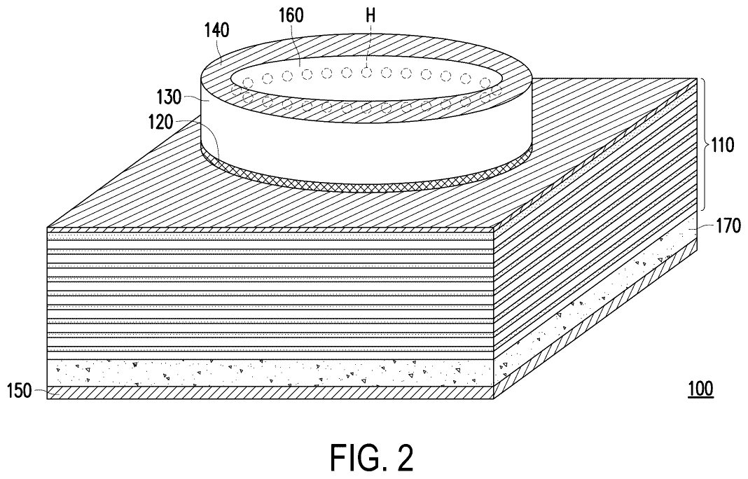

FIG. 1 is a cross-sectional schematic diagram illustrating a surface emitting laser device according to an embodiment of the disclosure, and FIG. 2 is a perspective schematic diagram of the surface emitting laser device of FIG. 1. Referring to FIG. 1 and FIG. 2, a surface emitting laser device 100 of this embodiment includes a first type distributed Bragg reflective layer 110, an active layer 120, a second type distributed Bragg reflective layer 130, and an oxide layer 132. The active layer 120 is disposed on the first type distributed Bragg reflective layer 110, and the second type distributed Bragg reflective layer 130 is disposed on the active layer 120. One of the first type distributed Bragg reflective layer 110 and the second type distributed Bragg reflective layer 130 is an N-type semiconductor layer, and the other is a P-type semiconductor layer. In this embodiment, the first type distributed Bragg reflective layer 110 is exemplified as an N-type semiconductor layer, while the second type distributed Bragg reflective layer is exemplified as a P-type semiconductor layer. However, in other embodiments, it may also be that the first type is P-type and the second type is N-type.

The oxide layer 132 is disposed on a side of the second type distributed Bragg reflective layer 130 adjacent to the active layer 120. The oxide layer 132 has an opening 131, through which the light emitted by the active layer 120 passes. The second type distributed Bragg reflective layer 130 has multiple voids H, which are located above the opening 131 and on the light path of the light emitted by the active layer 120. In this embodiment, the distributed Bragg reflection characteristics at these voids H are destroyed, thereby suppressing the laser light with multiple transverse modes (i.e., higher order transverse modes) from the active layer 120.

In this embodiment, the first type distributed Bragg reflective layer 110 and the second type distributed Bragg reflective layer 130 are stacked with multiple film layers with alternating high and low refractive indices. The formation of the oxide layer 132 may be implemented by means of a selective oxidation process on the film layer originally forming the second type distributed Bragg reflective layer 130. That is, the edge of the second type distributed Bragg reflective layer 130 is exposed to moisture and oxygen, allowing oxygen to penetrate into the film layer, thereby oxidizing it to form the oxide layer 132. In addition to the oxide layer 132, there is also some oxidation at the edge of the second type distributed Bragg reflective layer 130 above the oxide layer 132, forming an oxide layer 134.

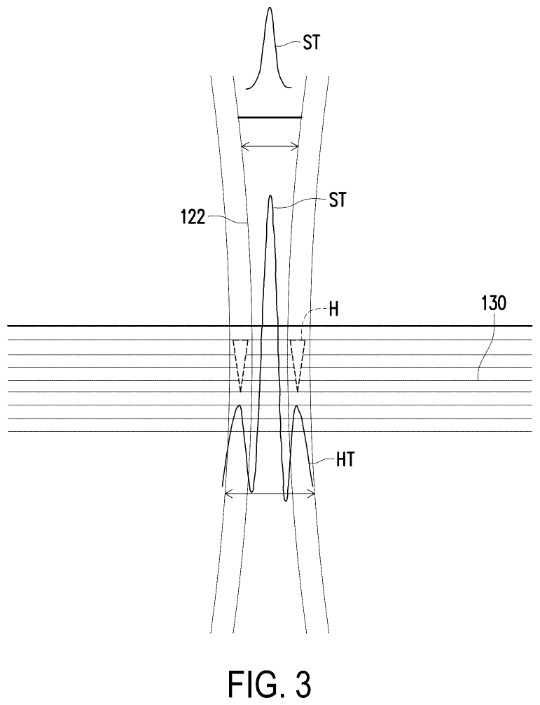

FIG. 3 illustrates the relationship between a transverse mode of laser light and voids in FIG. 1. Please refer to FIG. 1 to FIG. 3. As shown in FIG. 3, since the positions of the voids H correspond to the positions of higher order transverse modes HT of the laser light generated by the active layer 120, and the distributed Bragg reflection characteristics of the second type distributed Bragg reflective layer 130 at the voids H are destroyed by the voids H, therefore, the higher order transverse modes HT may be suppressed or even not generated. On the other hand, there are no voids H at the position of a single transverse mode ST of laser light 122 generated by the active layer 120, so that the single transverse mode is not affected by the voids H. In this way, the laser light 122 with a single transverse mode ST may be emitted outside the second type distributed Bragg reflective layer 130, enabling the surface emitting laser device 100 of this embodiment to achieve single transverse mode output.

In the surface emitting laser device 100 of this embodiment, the second type distributed Bragg reflective layer 130 has multiple voids H located above the opening 131. The distributed Bragg reflection characteristics at these voids H are destroyed, thereby suppressing the laser light with multiple transverse modes from the active layer 120. Therefore, the surface emitting laser device 100 may achieve single transverse mode output by means of a simple structure, while simultaneously having lower cost and higher yield.

In this embodiment, the voids H are arranged in at least one circle above the opening 131, and the position of this at least one circle may correspond to the position of the higher order transverse mode. In one embodiment, the voids H may be arranged periodically in at least one circle. Additionally, the voids H may be located at multiple different depths or at the same depth. Furthermore, in this embodiment, a diameter D1 of the opening 131 falls within the range of 8 microns to 15 microns. In this embodiment, since the voids H are utilized to suppress the higher order transverse modes, rather than relying solely on the opening 131 to suppress the higher order transverse modes, the size of the opening 131 of the oxide layer 132 formed by the selective oxidation process does not need to be very precise or very small (for example, it does not need to be smaller than 5 microns). Therefore, the yield of the selective oxidation process can be significantly improved. Moreover, compared to the distance between the opening 131 and the active layer 120, the distance between the voids H and the active layer 120 is greater, so the voids H are farther from the beam waist of the laser light 122 generated by the active layer 120, meaning that the beam has already expanded at the position of the voids H. As a result, the diameter of the circle formed by the voids H does not need to be very small (for example, it does not need to be smaller than 5 microns) to correspond to the position of higher order transverse modes. Therefore, the process yields for forming the voids H can be effectively improved.

In this embodiment, the surface emitting laser device 100 further includes an upper electrode 140, disposed in the peripheral region of the top of the second type distributed Bragg reflective layer 130. Furthermore, in this embodiment, the surface emitting laser device 100 further includes a lower electrode 150, disposed below the first type distributed Bragg reflective layer 110. A substrate 170 may be disposed between the first type distributed Bragg reflective layer 110 and the lower electrode 150. When a forward voltage is applied to the upper electrode 140 and the lower electrode 150, the active layer 120 emits light, and this light is reflected back and forth between the first type distributed Bragg reflective layer 110 and the second type distributed Bragg reflective layer 130 and resonate, then the laser light 122 is generated, and the laser light 122 may partially pass through the second type distributed Bragg reflective layer 130 and transmit to the outside.

In this embodiment, the surface emitting laser device 100 further includes a protective layer 160, disposed on the top of the second type distributed Bragg reflective layer 130, to protect the second type distributed Bragg reflective layer 130 and the film layers below it, such as the active layer 120.

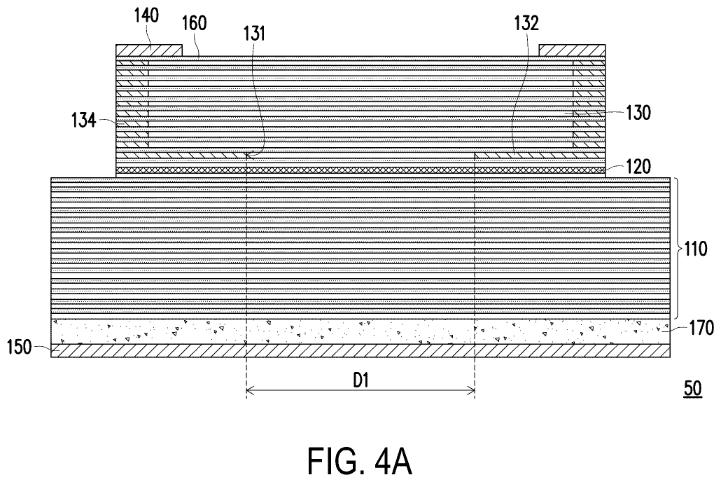

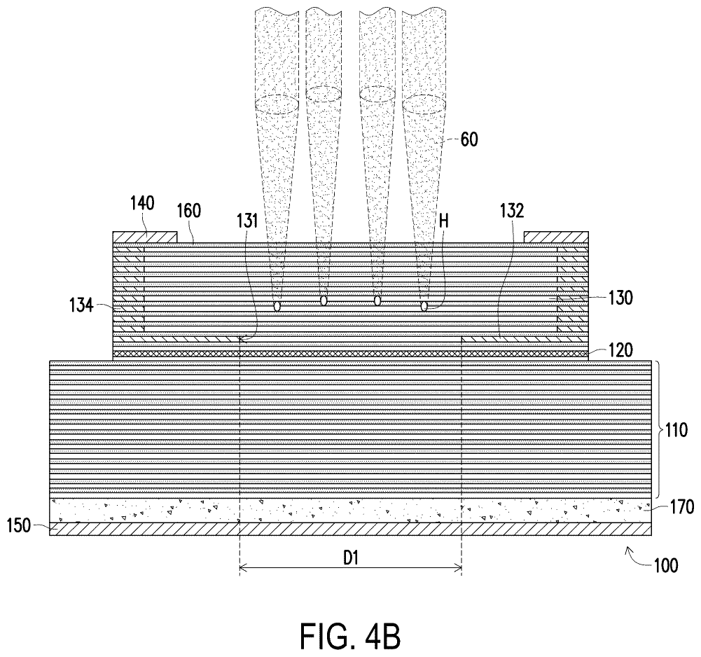

FIG. 4A and FIG. 4B are cross-sectional schematic diagrams used to illustrate the process flow of a manufacturing method for a surface emitting laser device according to an embodiment of the disclosure. Referring to FIG. 4A and FIG. 4B, the manufacturing method for the surface emitting laser device according to this embodiment may be used to manufacture the surface emitting laser device 100 of FIG. 1. The manufacturing method for the surface emitting laser device according to this embodiment includes the following steps. First, as illustrated in FIG. 4A, provide a surface emitting laser chip 50, which includes a first type distributed Bragg reflective layer 110, an active layer 120, a second type distributed Bragg reflective layer 130, and an oxide layer 132. The active layer 120 is disposed on the first type distributed Bragg reflective layer 110, and the second type distributed Bragg reflective layer 130 is disposed on the active layer 120. The oxide layer 132 is disposed on the side of the second type distributed Bragg reflective layer 130 adjacent the active layer 120, and the oxide layer 132 has an opening 131 for allowing the light emitted by the active layer 120 to pass through. Next, as illustrated in FIG. 4B, form multiple voids H within the second type distributed Bragg reflective layer 130 above the opening 131. In this embodiment, for example, an ultra-short pulse laser 60 is utilized to focus within the second type distributed Bragg reflective layer 130 to form multiple voids H above the opening 131. In this way, the surface emitting laser device 100 as shown in FIG. 1 can be formed. The distributed Bragg reflection characteristic at the voids H is destroyed, thereby suppressing the laser light with multiple transverse modes from the active layer 120.

Specifically, in this embodiment, by utilizing the ultra-short pulse laser 60 and controlling different focus depths, destructive voids H can be created in the second type distributed Bragg reflective layer 130 through intense nonlinear effects or multi-photon absorption effects in several pairs of film layers with alternating high and low refractive indexes near the epitaxial surface of the second type distributed Bragg reflective layer 130. By means of the intense nonlinear effects and multi-photon absorption induced by the ultra-short pulse laser, the voids H can be formed inside the component without damaging the surface. This transforms the high reflectivity originally formed by the epitaxial layers with periodically alternating refractive indices at the location of the voids H into a situation where the refractive index is destroyed periodically and thus cannot provide sufficient reflectivity to satisfy the laser gain requirement. Precisely controlling the irradiation region of the ultra-short pulse laser may effectively suppress the higher order transverse modes to achieve laser gain, ultimately resulting in single transverse mode output. In this embodiment, the ultra-short pulse laser 60 may be, for example, a femtosecond laser or a picosecond laser.

Moreover, the detailed structure of the surface emitting laser device 100 manufactured by the manufacturing method of the surface emitting laser device according to this embodiment is as described in the embodiments of FIG. 1 to FIG. 3 above, and therefore are not repeated in the following.

In the surface emitting laser device 100 of the above-mentioned embodiment and the manufacturing method of the surface emitting laser device in this embodiment, on a surface emitting laser structure with a distributed Bragg reflective layer that may have semiconductor epitaxial growth or dielectric or a hybrid of both, a structure with destructive voids H is formed by utilizing an ultra-short pulse laser focused on the surface of the second type distributed Bragg reflective layer 130. When focused inside the second type distributed Bragg reflective layer 130, in a situation where the energy density on the epitaxial layer surface is insufficient to form destructive damage, the original flat and closed structure of the component surface can be maintained without the need for additional surface thin film deposition. This may avoid the impact of moisture or oxygen causing a decrease in component reliability during long-term operation.

Furthermore, the manufacturing method of the surface emitting laser device in this embodiment may not require changing the epitaxial structure of the surface emitting laser, and does not need additional use of photolithography and etching. By means of controlling the focus depth, the voids H can be formed only inside the second type distributed Bragg reflective layer 130, therefore additional processes for surface coating or planarization are not required. Using a simple post-processing method, the higher order transverse mode can be suppressed to achieve single-mode output effect.

In the manufacturing method of the surface emitting laser device in this embodiment, by utilizing an ultra-short pulse laser, it may be focused at a pre-calculated depth. At the same time, by utilizing the characteristics of the ultra-short pulse laser, periodic voids H can be created inside the distributed Bragg reflective layer without damaging the component surface, thus maintaining the integrity of the appearance of the component.

Compared to voids made by traditional etching methods, the voids H formed by utilizing ultra-short pulse laser are located inside the second type distributed Bragg reflective layer 130, with the original dielectric coating film still on the surface to protect the interior of the component from being affected by external environment (e.g., humidity, oxygen, etc.), which may lead to a shortened component lifecycle.

Compared to the traditional method of suppressing higher order transverse modes by etching photonic crystals, which inevitably removes conductive semiconductor epitaxial layers when forming photonic crystals by etching, thus significantly increasing the series resistance of the component, leading to poor heat dissipation accompanied by decreased output power and limited high-frequency operation characteristics. By utilizing the ultra-short pulse laser 60 to form periodic void H structures with smaller dimensions, the impact on the current conduction path is relatively minor. This may improve the operational characteristics of single-mode surface emitting lasers compared to those made with traditional etched void photonic crystals.

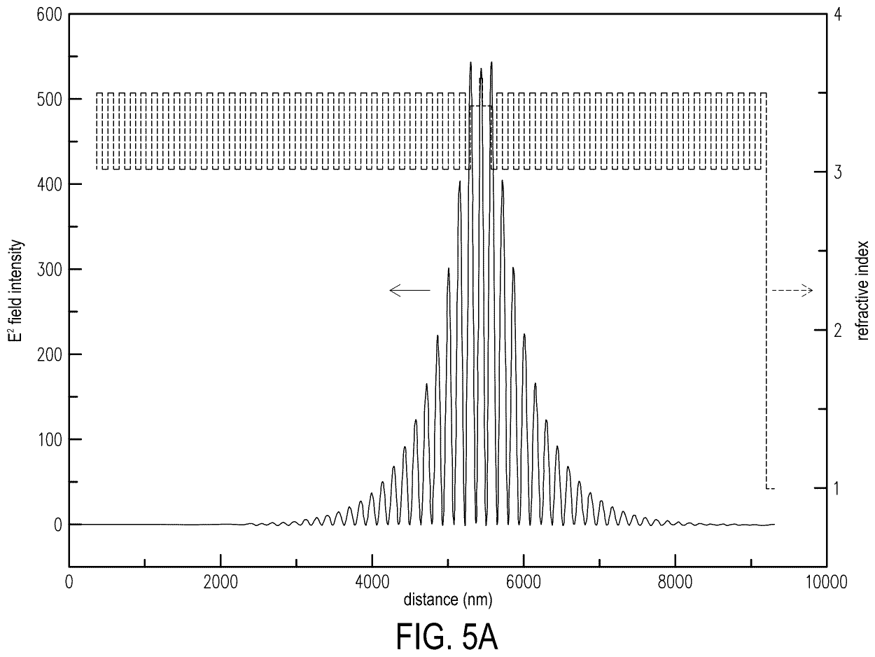

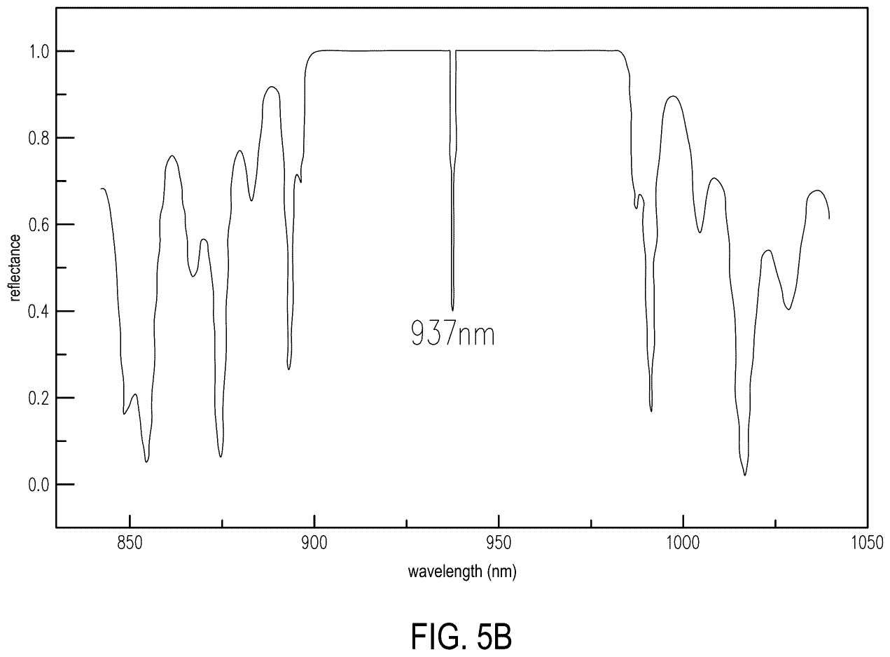

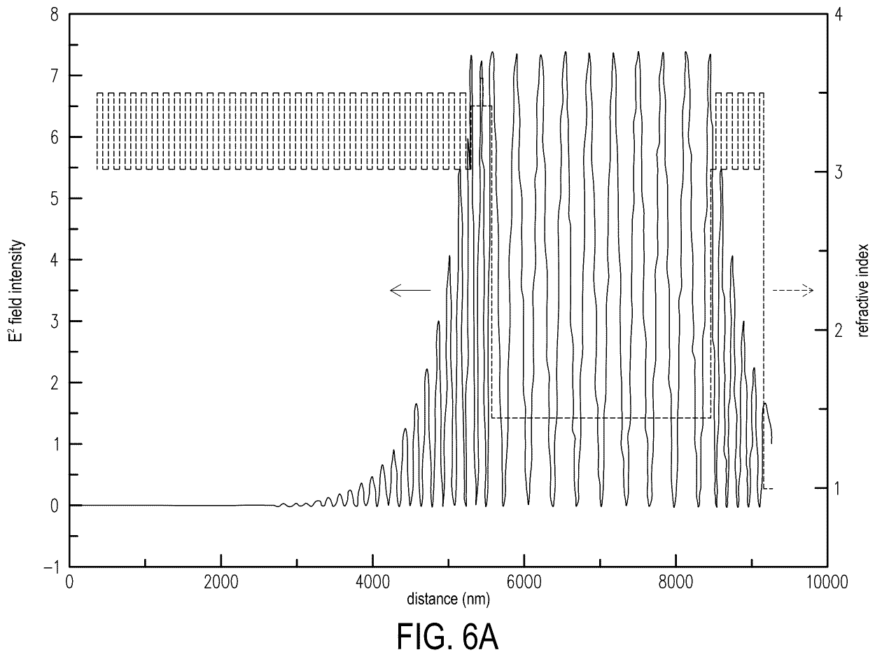

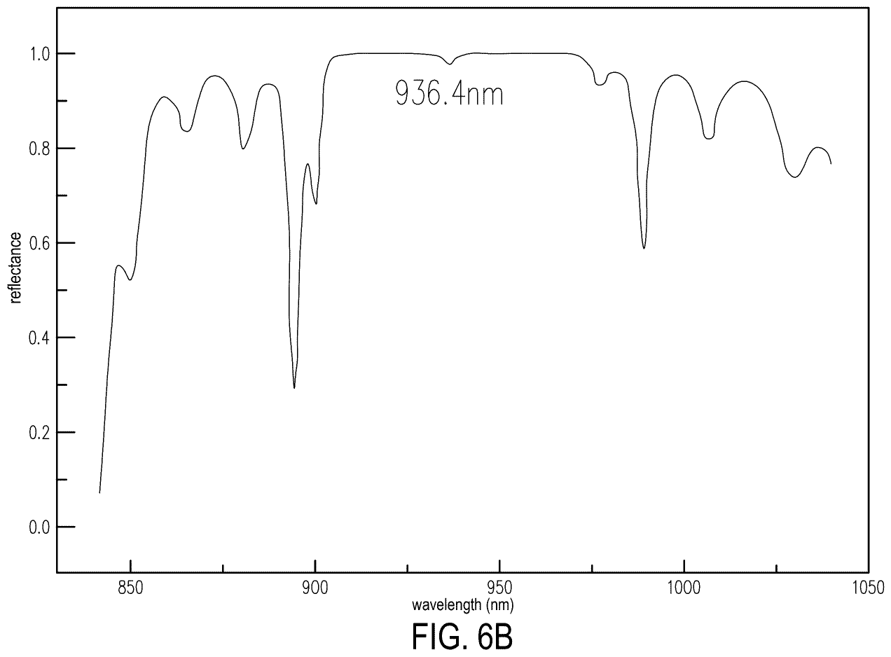

FIG. 5A is a distribution diagram of E² field intensity and refractive index relative to a profile depth of a surface emitting laser chip in FIG. 4A. FIG. 5B is a reflectance spectrum diagram of the surface emitting laser chip in FIG. 4A. FIG. 6A is a distribution diagram of E² field intensity and refractive index relative to a profile depth of the surface emitting laser device in FIG. 4B. FIG. 6B is a reflectance spectrum diagram of a surface emitting laser chip in FIG. 4B. Please refer to FIG. 4A, FIG. 5A, and FIG. 5B first. The active layer 120 of the surface emitting laser chip 50 may be, for example, a multiple quantum well layer with alternating stacks of indium gallium arsenide layers and gallium arsenide layers, or a multiple quantum well layer with alternating stacks of gallium arsenide layers and aluminum gallium arsenide layers, which may emit light with wavelengths from red to near-infrared, for example, it may emit light at 940 nanometers. For the surface emitting laser chip 50 without voids H formed, the distribution of refractive index and electric field intensity standing wave along its profile depth is shown in FIG. 5A, where E² in FIG. 5A and FIG. 6A represents the square of the absolute value of the electric field, from which the intensity of the electric field can be observed, and the distance on the horizontal axis represents the distance from the bottom of the surface emitting laser chip 50 or the surface emitting laser device 100 in the depth direction. Moreover, in FIG. 5A and FIG. 6A, the curve of E² field intensity is read from the scale on the left axis (as indicated by the arrow pointing left in the figure), while the curve of refractive index is read from the scale on the right axis (as indicated by the arrow pointing right in the figure). From FIG. 5A, it can be observed that although a well-designed epitaxial structure can ensure maximum electric field intensity near the active layer 120, with a critical gain of about 55.1 cm⁻¹, both the fundamental mode and higher order transverse mode can relatively easily obtain gain and achieve laser output conditions. Therefore, the surface emitting laser chip 50 without voids H formed outputs laser light in both fundamental mode and higher order transverse mode.

In contrast, referring to FIG. 4B, FIG. 6A, and FIG. 6B again, for the surface emitting laser device 100 with voids H formed, the distribution of refractive index and electric field intensity standing wave along its profile depth is shown in FIG. 6A. From FIG. 6A, it can be observed that the region focused by the ultra-short pulse laser irradiation undergoes physical or chemical changes such as dissociation due to nonlinear effects, transforming from semiconductor material into the structure of the voids H. This significantly increases the critical gain at the position of the higher order transverse mode to about 5853cm⁻1. The increase in critical gain means an increase in loss in this region, therefore requiring a larger gain to have a chance to achieve laser output. Consequently, under normal current injection conditions, only the regions not destroyed by the ultra-short pulse laser can obtain laser gain and emit laser light, thereby effectively suppressing the generation of the higher order transverse mode.

In one embodiment, the first type distributed Bragg reflective layer 110 may, for example, be a structure where N-type gallium arsenide layers and aluminum gallium arsenide layers are stacked alternately. The active layer 120 may, for example, be a multiple quantum well layer where gallium arsenide layers and aluminum gallium arsenide layers are stacked alternately. The second type distributed Bragg reflective layer 130 may, for example, be a structure where P-type gallium arsenide layers and aluminum gallium arsenide layers are stacked alternately. The material of the oxide layer 132 may, for example, be aluminum oxide. The material of the oxide layer 134 may, for example, be aluminum oxide. The material of the upper electrode 140 may, for example, be titanium, platinum, and gold stacked sequentially from the side closer to the second type distributed Bragg reflective layer 130 to the side farther from the second type distributed Bragg reflective layer 130, or the material of the upper electrode 140 may, for example, be gold-zinc alloy. The material of the lower electrode 150 may, for example, be nickel, gold, and gold-germanium alloy stacked sequentially from the side closer to the substrate 170 to the side farther from the substrate, or the material of the lower electrode 150 may, for example, be gold-zinc alloy. The material of the protective layer 160 may, for example, be silicon dioxide, silicon nitride, or aluminum oxide, etc. The material of the substrate 170 may, for example, be N-type gallium arsenide. However, the disclosure is not limited to this.

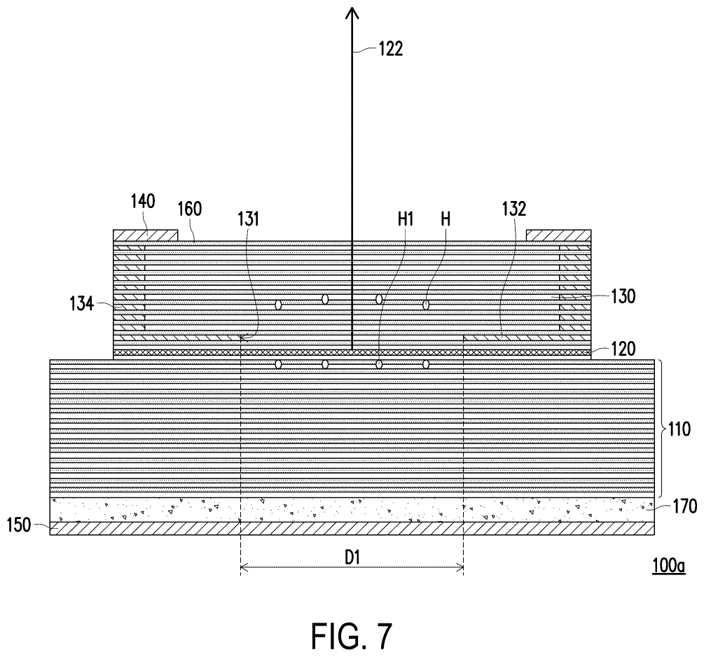

FIG. 7 is a cross-sectional schematic diagram of a surface emitting laser device according to another embodiment of the disclosure. Referring to FIG. 7, a surface emitting laser device 100a of this embodiment is similar to the surface emitting laser device 100 in FIG. 1, and the main differences between the two are described as follows. In the surface emitting laser device 100a of this embodiment, in addition to multiple voids H in the second type distributed Bragg reflective layer 130, there are also multiple voids H1 in the first type distributed Bragg reflective layer 110, the voids H1 being located below the opening 131. The distributed Bragg reflection characteristic at the voids H1 is also destroyed, thereby suppressing laser light with multiple transverse modes (i.e., higher order transverse modes) from the active layer 120. In a manufacturing method of the surface emitting laser device 100a of this embodiment, multiple voids H1 may also be formed in the first type distributed Bragg reflective layer 110 below the opening 131, for example, by utilizing ultra-short pulse laser to form the voids H1 and the voids H simultaneously in the first type distributed Bragg reflective layer 110 and the second type distributed Bragg reflective layer 130 at different focus depths, to form the voids H1 and the voids below and above the opening 131 respectively.

In summary, in the surface emitting laser device according to the embodiment of the disclosure, the second type distributed Bragg reflective layer has multiple voids located above the opening, or both the first type distributed Bragg reflective layer and the second type distributed Bragg reflective layer have voids located below and above the opening respectively. The distributed Bragg reflection characteristic at the voids is destroyed, thereby suppressing laser light with multiple transverse modes from the active layer. Therefore, the surface emitting laser device according to the embodiment of the disclosure may achieve single transverse mode output by means of a simple structure, while having lower cost and higher yield. In the manufacturing method of the surface emitting laser device according to the embodiment of the disclosure, ultra-short pulse laser is utilized to focus within the second type distributed Bragg reflective layer to form multiple voids above the opening, or ultra-short pulse laser is utilized simultaneously in the first type and second type distributed Bragg reflective layers at different focus depths to form voids below and above the opening respectively. The distributed Bragg reflection characteristic at the voids is destroyed, thereby suppressing laser light with multiple transverse modes from the active layer. Therefore, the manufacturing method of the surface emitting laser device according to the embodiment of the disclosure may implement simple, lower-cost, and higher-yield process steps to manufacture a surface emitting laser device that can achieve single transverse mode output.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A surface emitting laser device, comprising:
a first type distributed Bragg reflective layer;
an active layer, disposed on the first type distributed Bragg reflective layer;
a second type distributed Bragg reflective layer, disposed on the active layer; and
an oxide layer, disposed on a side of the second type distributed Bragg reflective layer adjacent to the active layer, wherein the oxide layer has an opening, and light emitted by the active layer passes through the opening;
wherein, the second type distributed Bragg reflective layer has a plurality of voids, the voids are located above the opening, and are located on a light path of the light emitted by the active layer.

2. The surface emitting laser device according to claim 1, wherein the voids are arranged in at least one circle above the opening.

3. The surface emitting laser device according to claim 2, wherein the voids are periodically arranged in at least one circle.

4. The surface emitting laser device according to claim 1, wherein a diameter of the opening falls within a range of 8 micrometers to 15 micrometers.

5. The surface emitting laser device according to claim 1, wherein one of the first type distributed Bragg reflective layer and the second type distributed Bragg reflective layer is an N-type semiconductor layer, and the other of the first type distributed Bragg reflective layer and the second type distributed Bragg reflective layer is a P-type semiconductor layer.

6. The surface emitting laser device according to claim 1, further comprising an upper electrode disposed on a peripheral region of a top of the second type distributed Bragg reflective layer.

7. The surface emitting laser device according to claim 1, further comprising a protective layer disposed on a top of the second type distributed Bragg reflective layer.

8. The surface emitting laser device according to claim 1, wherein the first type distributed Bragg reflective layer also has a plurality of voids located below the opening.

9. A manufacturing method of a surface emitting laser device, comprising:
providing a surface emitting laser chip, wherein the surface emitting laser chip comprises a first type distributed Bragg reflective layer, an active layer, a second type distributed Bragg reflective layer, and an oxide layer, the active layer is disposed on the first type distributed Bragg reflective layer, the second type distributed Bragg reflective layer is disposed on the active layer, the oxide layer is disposed on a side of the second type distributed Bragg reflective layer adjacent to the active layer, the oxide layer has an opening for allowing light emitted by the active layer to pass through; and
forming a plurality of voids in the second type distributed Bragg reflective layer above the opening.

10. The manufacturing method of the surface emitting laser device according to claim 9, wherein the voids are arranged in at least one circle above the opening.

11. The manufacturing method of the surface emitting laser device according to claim 10, wherein the voids are periodically arranged in at least one circle.

12. The manufacturing method of the surface emitting laser device according to claim 9, wherein a diameter of the opening falls within a range of 8 micrometers to 15 micrometers.

13. The manufacturing method of the surface emitting laser device according to claim 9, wherein one of the first type distributed Bragg reflective layer and the second type distributed Bragg reflective layer is an N-type semiconductor layer, and the other of the first type distributed Bragg reflective layer and the second type distributed Bragg reflective layer is a P-type semiconductor layer.

14. The manufacturing method of the surface emitting laser device according to claim 9, wherein forming the voids in the second type distributed Bragg reflective layer above the opening utilizes an ultra-short pulse laser focused in the second type distributed Bragg reflective layer to form the voids above the opening.

15. The manufacturing method of the surface emitting laser device according to claim 14, wherein the ultra-short pulse laser is a femtosecond laser or a picosecond laser.

16. The manufacturing method of the surface emitting laser device according to claim 14, wherein the ultra-short pulse laser creates destructive voids in the second type distributed Bragg reflective layer by means of nonlinear effects or multi-photon absorption effects.

17. The manufacturing method of the surface emitting laser device according to claim 9, further comprising also forming a plurality of voids in the first type distributed Bragg reflective layer below the opening.
